(19) United States
(12) Patent Application Publication
(10) Pub. No.: US 2025/0267850 A1
(43) Pub. Date: Aug. 21, 2025

(54) INTEGRATED CIRCUIT DEVICE AND METHOD OF MANUFACTURING THE SAME

(71) Applicant: Samsung Electronics Co., Ltd., Suwon-si (KR)

(72) Inventors: Gyunghyun YOON, Suwon-si (KR); Jiho PARK, Suwon-si (KR); Junhyeok AHN, Suwon-si (KR)

(73) Assignee: Samsung Electronics Co., Ltd., Suwon-si (KR)

(21) Appl. No.: 19/010,773

(22) Filed: Jan. 6, 2025

(30) Foreign Application Priority Data
Feb. 16, 2024 (KR) 10-2024-0022812

(51) Int. Cl. H10B 12/00

(52) U.S. Cl. CPC H10B 12/34; H10B 12/053

(57) ABSTRACT

An integrated circuit device includes a substrate comprising a cell array area and at least one interface area, the cell array area including a plurality of active areas, the at least one interface area including an insulating interface structure, a gate structure extending across the plurality of active areas in a first lateral direction, the gate structure including a first metal pattern, a line pattern, and a second metal pattern, the first metal pattern including an extension portion and a landing portion, the extension portion vertically overlapping the plurality of active areas, and the landing portion vertically overlapping the insulating interface structure, the line pattern on the extension portion of the first metal pattern, and the second metal pattern between the first metal pattern and the line pattern.

### CROSS-REFERENCE TO RELATED APPLICATION

This U.S. non-provisional application claims the benefit of priority under 35 U.S.C. § 119 to Korean Patent Application No. 10-2024-0022812, filed on Feb. 16, 2024, in the Korean Intellectual Property Office, the disclosure of which is incorporated by reference herein in its entirety.

### BACKGROUND

Various example embodiments of the inventive concepts relate to an integrated circuit (IC) device, a system including the IC device, and/or a method of manufacturing the IC device, and more particularly, to an IC device having a buried channel array transistor (BCAT), a system including the same, and/or a method of manufacturing the same, etc.

In recent years, as the integration density of IC devices has gradually increased, a structure of an IC device having a BCAT in which a plurality of word lines are buried in a substrate has been proposed. Accordingly, various studies are being conducted to improve and/or stabilize operations and reliability of BCATs.

### SUMMARY

Various example embodiments of the inventive concepts provide an integrated circuit (IC) device with improved reliability.

Various example embodiments of the inventive concepts also provide a method of manufacturing an IC device with improved reliability.

According to at least one example embodiment of the inventive concepts, there is provided an IC device. The IC device includes a substrate comprising a cell array area and at least one interface area, the cell array area including a plurality of active areas, the at least one interface area, a gate structure extending across the plurality of active areas in a first lateral direction, the gate structure partially extending into the insulating interface structure of the interface area, the gate structure including a first metal pattern, a line pattern, and a second metal pattern, the first metal pattern including an extension portion and a landing portion, the extension portion vertically overlapping the plurality of active areas, and the landing portion vertically overlapping the insulating interface structure, the line pattern on the extension portion of the first metal pattern, and the second metal pattern between the first metal pattern and the line pattern, and at least one conductive contact contacting the landing portion of the first metal pattern, the at least one conductive contact being spaced apart from the second metal pattern.

According to at least one example embodiment of the inventive concepts, there is provided an IC device. The IC device includes a substrate including a cell array area, the cell array area including a plurality of active areas, an insulating interface structure surrounding the cell array area, the insulating interface structure having a closed loop shape in a view from above, a gate structure extending across the plurality of active areas in a first lateral direction, the gate structure partially extending into the insulating interface structure, and at least one conductive contact contacting the gate structure on the insulating interface structure, the gate structure including a first metal pattern, a second metal pattern, and a line pattern, the first metal pattern including an extension portion and a landing portion, the first metal pattern having a stepped structure where the extension portion meets the landing portion, the extension portion vertically overlapping the plurality of active areas and extending in the first lateral direction, and the landing portion vertically overlapping the insulating interface structure and contacting the at least one conductive contact at a higher vertical level than an upper surface of the extension portion, the second metal pattern covering the upper surface of the extension portion and a sidewall of the landing portion, the sidewall facing the cell array area, the line pattern spaced apart from the first metal pattern, and the second metal pattern between the line pattern and the first metal pattern.

According to at least one example embodiment of the inventive concepts, there is provided an IC device. The IC device includes a substrate including a cell array area, a peripheral circuit area, and an interface area, the cell array area including a plurality of active areas, the peripheral circuit area including at least one peripheral circuit active area, and the interface area including an insulating interface structure, the interface area between the cell array area and the peripheral circuit area, an insulating interface structure surrounding the plurality of active areas, a gate structure extending across the plurality of active areas in a first lateral direction in the cell array area, the gate structure partially extending into the insulating interface structure of the interface area, the gate structure including a first metal pattern, a second metal pattern, and a line pattern, the first metal pattern including an extension portion and a landing portion, the first metal pattern having a stepped structure where the extension portion meets the landing portion, the extension portion vertically overlapping the plurality of active areas and extending in the first lateral direction, and the landing portion vertically overlapping the insulating interface structure and having an upper surface at a higher vertical level than an upper surface of the extension portion, the second metal pattern covering the upper surface of the extension portion and a sidewall of the landing portion, the sidewall facing the cell array area, the line pattern spaced apart from the first metal pattern, and the second metal pattern between the line pattern and the first metal pattern, and at least one conductive contact contacting the upper surface of the landing portion of the first metal pattern, the at least one conductive contact being spaced apart from the second metal pattern.

### BRIEF DESCRIPTION OF THE DRAWINGS

Various example embodiments of the inventive concepts will be more clearly understood from the following detailed description taken in conjunction with the accompanying drawings in which:

FIG. 1 is a layout diagram of a schematic configuration of an integrated circuit (IC) device according to some example embodiments;

FIG. 2 is an enlarged layout diagram of region “EX1” of FIG. 1 according to some example embodiments;

FIG. 3 is a cross-sectional view taken along line X1-X1′ of FIG. 2 according to some example embodiments;

FIG. 4 is an enlarged layout diagram of region “EX2” of FIG. 3 according to some example embodiments;

FIG. 5 is a cross-sectional view of an IC device according to some example embodiments;

FIG. 6 is a cross-sectional view of an IC device according to some example embodiments;

FIG. 7 is a cross-sectional view of an IC device according to some example embodiments;

FIG. 8 is a cross-sectional view of an IC device according to some example embodiments;

FIGS. 9A to 9K are cross-sectional views of a process sequence of a method of manufacturing an IC device, according to some example embodiments; and

FIGS. 10A to 10C are cross-sectional views of a process sequence of a method of manufacturing an IC device, according to some example embodiments.

### DETAILED DESCRIPTION

Hereinafter, various example embodiments of the inventive concepts will be described in detail with reference to the accompanying drawings. The same reference numerals are used to denote the same elements in the drawings, and repeated descriptions thereof are omitted.

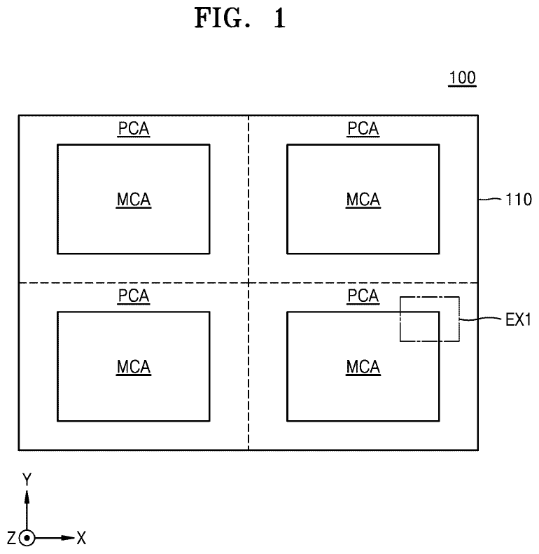

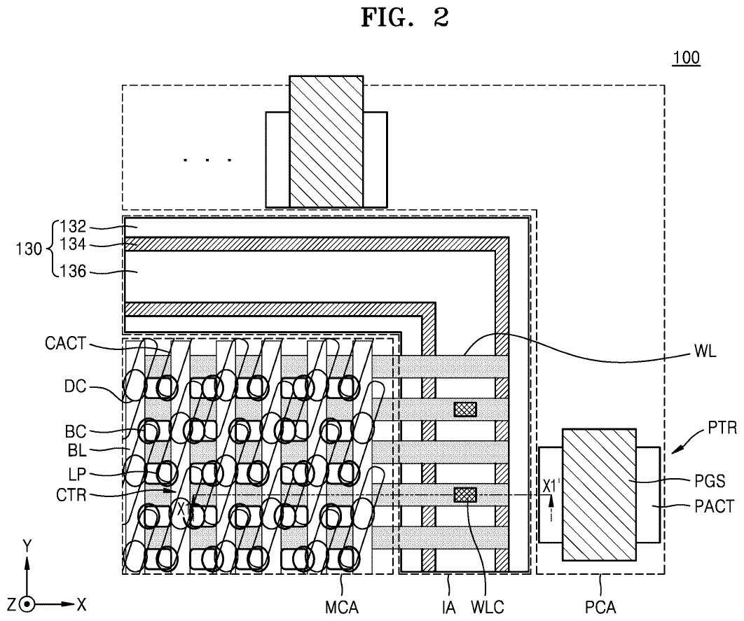

FIG. 1 is a layout diagram of a schematic configuration of an integrated circuit (IC) device 100 according to some example embodiments. FIG. 2 is an enlarged layout diagram of region “EX1” of FIG. 1 according to some example embodiments.

Referring to FIGS. 1 and 2, the IC device 100 may include a semiconductor substrate 110 including at least one cell array area MCA and at least one peripheral circuit area PCA, but is not limited thereto. According to some example embodiments, the semiconductor substrate 110 may include at least one interface area IA between a cell array area MCA and a peripheral circuit area PCA, but the example embodiments are not limited thereto.

According to some example embodiments, the cell array area MCA may be a memory cell area of a dynamic random access memory (DRAM) device, and the peripheral circuit area PCA may be a core area and/or a peripheral circuit area of the DRAM device, but the example embodiments are not limited thereto. For example, the cell array area MCA may include at least one cell transistor CTR and at least one capacitor structure (not shown) connected to the at least one cell transistor CTR, and the peripheral circuit area PCA may include at least one peripheral circuit transistor PTR configured to transmit signals and/or power to the at least one cell transistor CTR included in the cell array area MCA, etc. In some example embodiments, the peripheral circuit transistor PTR may include various circuits, such as a command decoder, a control logic, an address buffer, a row decoder, a column decoder, a sense amplifier, and/or a data input/output (I/O) circuit, etc.

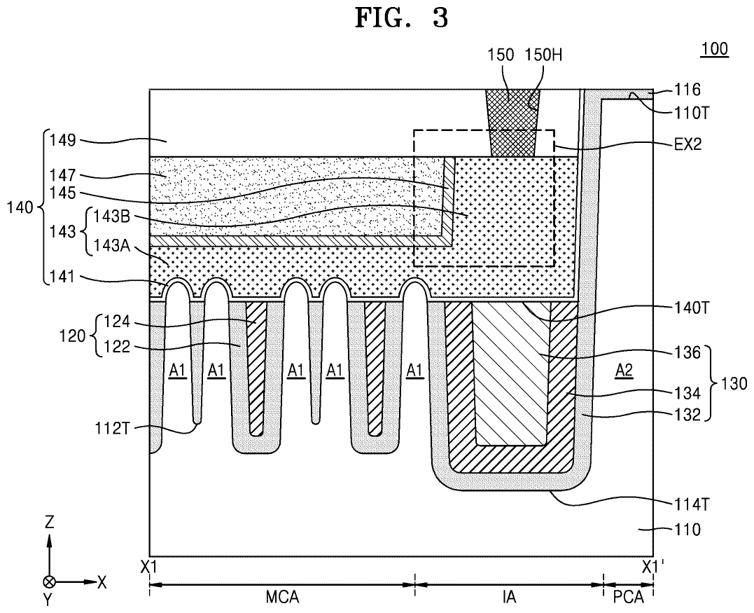

According to some example embodiments, the interface area IA may include an insulating interface structure (e.g., insulating interface structure 130 in FIG. 3, etc.) configured to electrically insulate the cell array area MCA from the peripheral circuit area PCA. For example, in a view from above (e.g., from the Z direction), the insulating interface structure 130 may have a closed loop shape surrounding a plurality of active areas CACT, but is not limited thereto.

According to some example embodiments, the semiconductor substrate 110 may include a plurality of active areas CACT and PACT. According to some example embodiments, a plurality of active areas CACT of the cell array area MCA may be defined by a device isolation structure (e.g., device isolation structure 112 in FIG. 3, etc.). At least one peripheral circuit active area PACT may be defined in the peripheral circuit area PCA. The plurality of active areas CACT of the cell array area MCA may be apart from the peripheral circuit active area PACT of the peripheral circuit area PCA with the insulating interface structure 130 therebetween, but the example embodiments are not limited thereto. The peripheral circuit transistor PTR may include the peripheral circuit active area PACT, a peripheral circuit gate electrode PGS, and/or a peripheral circuit gate dielectric layer (not shown) between the peripheral circuit active area PACT and the peripheral circuit gate electrode PGS, etc.

According to some example embodiments, in the cell array area MCA, the plurality of active areas CACT may be arranged to have a major axis extending in an oblique direction to a first lateral direction (e.g., X direction) and a second lateral direction (e.g., Y direction) that intersects the first lateral direction (e.g., X direction), but the example embodiments are not limited thereto. According to some example embodiments, the plurality of active areas CACT may be apart from each other in a lateral direction (e.g., X direction and/or Y direction), etc.

According to some example embodiments, a plurality of word lines WL may intersect the plurality of active areas CACT and extend parallel to each other in the first lateral direction (e.g., X direction). According to some example embodiments, a plurality of bit lines BL may extend parallel to each other in the second lateral direction (e.g., Y direction) on the plurality of word lines WL. The plurality of bit lines BL may be connected to the plurality of active areas CACT through direct contacts DC. Each of the plurality of word lines WL may receive a driving voltage through the word line contact WLC connected to the corresponding one of the word lines WL in the interface area IA.

According to some example embodiments, a plurality of buried contacts BC may be between two adjacent bit lines of the plurality of bit lines BL. According to some example embodiments, the plurality of buried contacts BC may be arranged in a matrix form in the first lateral direction (e.g., X direction) and the second lateral direction (e.g., Y direction). According to some example embodiments, a plurality of landing pads LP may be respectively on the plurality of buried contacts BC, but the example embodiments are not limited thereto. According to some example embodiments, each of the plurality of landing pads LP may at least partially overlap the buried contact BC in a vertical direction (e.g., Z direction), etc. According to some example embodiments, the plurality of buried contacts BC and the plurality of landing pads LP may be configured to connect a lower electrode (not shown) of a capacitor (not shown) formed on the plurality of bit lines BL to the active area CACT, but are not limited thereto.

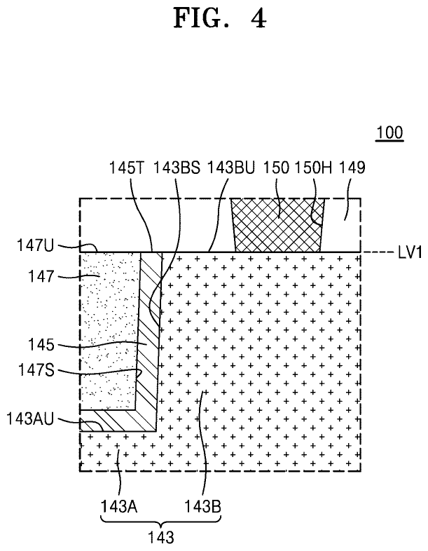

FIG. 3 is a cross-sectional view taken along line X1-X1′ of FIG. 2, illustrating some components of an IC device 100 according to some example embodiments. FIG. 4 is an enlarged layout diagram of region “EX2” of FIG. 3 according to some example embodiments. Although the illustration of the direct contact DC, the bit line BL, the buried contact BC, and the landing pad LP described with reference to FIG. 2 are omitted in FIGS. 3 and 4, unshown components may also be fully understood by one skilled in the art.

Referring to FIGS. 3 and 4 together with FIG. 2, the IC device 100 may include a substrate 110 including a plurality of active areas A1 defined in a cell array area MCA and at least one peripheral circuit active area A2 defined in a peripheral circuit area PCA, but is not limited thereto. According to some example embodiments, the plurality of active areas A1 and the peripheral circuit active area A2 may be defined by at least one device isolation trench 112T and/or at least one interface trench 114T. The device isolation trench 112T may be filled by a device isolation structure 120, and the interface trench 114T may be filled by an insulating interface structure 130. The plurality of active areas A1 may respectively correspond to the plurality of active areas CACT described with reference to FIG. 2 and may hereinafter be referred to as cell active areas, but are not limited thereto. The peripheral circuit active area A2 may correspond to the peripheral circuit active area PACT described with reference to FIG. 2, but is not limited thereto.

According to some example embodiments, the substrate 110 may include silicon, for example, single-crystalline silicon, polycrystalline silicon, and/or amorphous silicon, etc., but is not limited thereto. According to other some example embodiments, the substrate 110 may include at least one selected from germanium (Ge), silicon germanium (SiGe), silicon carbide (SiC), gallium arsenide (GaAs), indium arsenide (InAs), and/or indium phosphide (InP), etc. As used herein, each of the terms “SiGe,” “SiC,” “GaAs,” “InAs,” and “InP” refers to a material including elements included therein, without referring to a chemical formula representing a stoichiometric relationship, and terms described below may be similarly understood. According to some example embodiments, the substrate 110 may include at least one conductive region, for example, a doped well and/or a doped structure, etc.

In the cell array area MCA, the device isolation structure 120 may include at least one first insulating film 122 and/or at least one second insulating film 124, etc., but is not limited thereto, and for example, the device isolation structure 120 may omit one of the two insulating films, or may include greater than two insulating films, etc. A portion of the device isolation structure 120 may have a structure in which the first insulating film 122 and the second insulating film 124 are sequentially stacked, but is not limited thereto. Of the device isolation trench 112T, a first region, which has a relatively small width in a lateral direction (e.g., the X direction and/or the Y direction), may be filled by only the first insulating film 122, and a second region, which has a relatively large width in the lateral direction, may be filled by the first insulating film 122 and the second insulating film 124. For example, in the second region, the first insulating film 122 may cover a bottom surface and an inner wall of the device isolation trench 112T and fill a portion of the device isolation trench 112T, and the second insulating film 124 may fill the remaining space of the device isolation trench 112T on the first insulating film 122, etc., but the example embodiments are not limited thereto.

In an interface area IA, the insulating interface structure 130 may include a first insulating liner 132 and a second insulating liner 134, which are sequentially stacked on a bottom surface and an inner wall of the interface trench 114T, and a buried insulating film 136 filling the interface trench 114T on the second insulating liner 134, but the example embodiments are not limited thereto, and for example, the insulating interface structure 130 may include a greater or lesser number of insulating liners, may omit the buried insulating film, and/or may have a plurality of insulating films.

In some example embodiments, each of the first insulating film 122, the first insulating liner 132, and the buried insulating film 136 may include an oxide film, and each of the second insulating film 124 and the second insulating liner 134 may include a nitride film, but are not limited thereto. In some example embodiments, the oxide film of each of the first insulating film 122 and the first insulating liner 132 may include a silicon oxide film formed by using an atomic layer deposition (ALD) process, but the example embodiments are not limited thereto. In some example embodiments, each of the second insulating film 124 and the second insulating liner 134 may include a silicon nitride film, but are not limited thereto. In some example embodiments, the silicon oxide film included in the buried insulating film 136 may be tonen silazene (TOSZ), a high-density plasma (HDP) oxide film, and/or an undoped silicate glass (USG) oxide film, etc. In some other example embodiments, the oxide film included in the buried insulating film 136 may include a spin-on-glass (SOG) oxide film including silicate, siloxane, methyl silsesquioxane (MSQ), hydrogen silsesquioxane (HSQ), polysilazane, or any combinations thereof, without being limited thereto.

In some example embodiments, the IC device 100 may include an insulating thin film covering an upper surface 110T of the substrate 110, etc. In some example embodiments, the insulating thin film 116 may include the same material as an insulating material included in the first insulating liner 132, without being limited thereto.

According to some example embodiments, in the cell array area MCA, a plurality of gate trenches 140T may be formed to intersect the plurality of active areas A1 and the device isolation structure 120, and may extend in the first lateral direction (e.g., X direction). According to some example embodiments, each of the plurality of gate trenches 140T may include a portion extending into the interface area IA. For example, in the interface area IA, each of the plurality of gate trenches 140T may intersect at least a portion of the insulating interface structure 130. The plurality of gate trenches 140T may have a plurality of line shapes extending parallel to each other in the first lateral direction (e.g., X direction), but are not limited thereto.

According to some example embodiments, the plurality of gate trenches 140T may be respectively filled by a plurality of gate structures 140. According to some example embodiments, the plurality of gate structures 140 may extend in the first lateral direction (e.g., X direction) and may be apart from each other in the second lateral direction (e.g., Y direction). According to some example embodiments, the plurality of gate structures 140 may extend across the plurality of active areas A1 and the device isolation structure 120 in the cell array area MCA, but are not limited thereto. Both ends of each of the plurality of gate structures 140 in the first lateral direction (e.g., X direction) may partially extend into the interface area IA and/or may partially extend into the insulating interface structure 130. In some example embodiments, the plurality of gate structures 140 may be spaced apart from the peripheral circuit active area A2 with at least a portion of the insulating interface structure 130 therebetween, or in other words, a portion of the insulating interface structure 130 may be between the plurality of gate structures 140 and the peripheral circuit active area A2. The plurality of gate structures 140 may correspond to the plurality of word lines WL described with reference to FIG. 2, but are not limited thereto. According to some example embodiments, each of the plurality of gate structures 140 may include a gate dielectric film 141, a first metal pattern 143, a second metal pattern 145, a line pattern 147, and/or an insulating capping pattern 149, etc., but the example embodiments are not limited thereto.

According to some example embodiments, a portion of a bottom surface of the gate trench 140T exposing the active area A1 of the substrate 110 may be at a higher vertical level (e.g., in the Z direction) than portions of the bottom surface of the gate trench 140T covering the device isolation structure 120 and/or the insulating interface structure 130. For example, each of the plurality of active areas A1 may include a saddle fin portion at a higher vertical level (e.g., in the Z direction) than the device isolation structure 120 and/or the insulating interface structure 130 in a region where the corresponding one of the active areas A1 overlaps the gate structure 140 in the vertical direction (e.g., Z direction), but the example embodiments are not limited thereto. The saddle fin portion of each of the plurality of active areas A1 may be covered by the first metal pattern 143, and a saddle fin field-effect transistor (e.g., saddle FinFET) may be formed in each of the plurality of active areas A1. As used herein, the term “vertical level” refers to a distance from the upper surface 110T of the substrate 110 in a Z direction or a −Z direction.

According to some example embodiments, the gate dielectric film 141 may conformally cover the bottom surface and/or the inner wall of the gate trench 140T, etc. For example, the gate dielectric film 141 may have a shape corresponding to a profile of the bottom surface and/or the inner wall of the gate trench 140T, etc. For example, the gate dielectric film 141 may include a portion contacting the saddle fin portion of each of the plurality of active areas A1, a portion contacting the device isolation structure 120, and/or a portion contacting the insulating interface structure 130, etc.

In some example embodiments, the gate dielectric film 141 may include at least one selected from silicon oxide, silicon nitride, silicon oxynitride, oxide/nitride/oxide (ONO), a high-k dielectric material having a higher dielectric constant than silicon oxide, etc., or any combinations thereof.

According to some example embodiments, the first metal pattern 143 may fill at least a portion of the gate trench 140T on the gate dielectric film 141 and may extend in the first lateral direction (e.g., X direction). In some example embodiments, a bottom surface of the first metal pattern 143 may have a concave-convex shape corresponding to a bottom profile of the gate trench 140T. In some example embodiments, the saddle fin portion of each of the plurality of active areas A1 may be spaced apart from the first metal pattern 143 with the gate dielectric film 141 therebetween, or in other words, the gate dielectric film 141 may be between the saddle fin portions of each of the active areas A1 and the first metal pattern 143.

According to some example embodiments, the first metal pattern 143 may include an extension portion 143A vertically overlapping and/or covering the plurality of active areas A1 in the cell array area MCA and/or may include a landing portion 143B vertically overlapping and/or covering the insulating interface structure 130 in the interface area IA. The landing portion 143B may extend from an end portion of the extension portion 143A in the first lateral direction (e.g., X direction), but is not limited thereto. For example, although only one end portion of the extension portion 143A in the first lateral direction (e.g., X direction) is illustrated in FIGS. 2 and 3, two landing portions 143B may respectively extend from both end portions of the extension portion 143A in the first lateral direction (e.g., X direction).

In some example embodiments, an upper surface 143BU of the landing portion 143B may be at a higher vertical level than an upper surface 143AU of the extension portion 143A. In some example embodiments, the upper surface 143BU of the landing portion 143B may be at a first vertical level LV1, and the upper surface 143AU of the extension portion 143A may be at a vertical level lower than the first vertical level LV1. For example, the upper surface 143BU of the landing portion 143B may be closer to the upper surface 110T of the substrate 110 than the upper surface 143AU of the extension portion 143A. In some example embodiments, a first height, which is a length of the extension portion 143A in the vertical direction (e.g., Z direction), may be less than a second height, which is a length of the landing portion 143B in the vertical direction (e.g., Z direction), but is not limited thereto. For example, the first metal pattern 143 may have a stepped structure at a point where the extension portion 143A meets the landing portion 143B.

In some example embodiments, the upper surface 143AU of the extension portion 143A may extend planarly and/or relatively planarly. For example, in a vertical cross-sectional view, the upper surface 143AU of the extension portion 143A may extend linearly. In some example embodiments, a bottom surface of the extension portion 143A may have a concave-convex shape corresponding to the bottom profile of the gate trench 140T, but is not limited thereto.

In some example embodiments, the landing portion 143B may have a first sidewall 143BS and a second sidewall, but is not limited thereto. The second sidewall may face the cell array area MCA at a higher vertical level than the extension portion 143A. The second sidewall may be opposite to the first sidewall 143BS in the first lateral direction (e.g., X direction). In some example embodiments, the second sidewall may face the peripheral circuit active area A2 with a portion of the insulating interface structure 130 therebetween. In some example embodiments, the first sidewall 143BS of the landing portion 143B may meet the upper surface 143AU of the extension portion 143A.

In some example embodiments, the first sidewall 143BS of the landing portion 143B may be inclined with respect to the upper surface 143AU of the extension portion 143A, but is not limited thereto. In some example embodiments, the first sidewall 143BS of the landing portion 143B may be inclined downward (e.g., declined) in a direction away from the peripheral circuit active area A2, etc. For example, at a higher vertical level than the upper surface 143AU of the extension portion 143A, a width of the landing portion 143B in the first lateral direction (e.g., X direction) may increase the further away it is from the upper surface 110T of the substrate 110, but is not limited thereto.

In some other example embodiments, the first sidewall 143BS of the landing portion 143B may be perpendicular to the upper surface 143AU of the extension portion 143A. In still other example embodiments, the first sidewall 143BS of the landing portion 143B may be inclined upward in the direction away from the peripheral circuit active area A2. For example, at a higher vertical level than the upper surface 143AU of the extension portion 143A, a width of the landing portion 143B in the first lateral direction (e.g., X direction) may reduce the further away it is from the upper surface 110T of the substrate 110.

According to some example embodiments, the second metal pattern 145 may cover the upper surface 143AU of the extension portion 143A and the first sidewall 143BS of the landing portion 143B, but is not limited thereto. In some example embodiments, the second metal pattern 145 may have a shape corresponding to profiles of the upper surface 143AU of the extension portion 143A and/or the first sidewall 143BS of the landing portion 143B, but is not limited thereto. For example, the second metal pattern 145 may conformally cover the upper surface 143AU of the extension portion 143A and/or the first sidewall 143BS of the landing portion 143B to a constant thickness and may be in contact with the upper surface 143AU of the extension portion 143A and/or the first sidewall 143BS of the landing portion 143B, etc.

In some example embodiments, the second metal pattern 145 may not contact the upper surface 143BU of the landing portion 143B, but is not limited thereto. For example, the second metal pattern 145 may not vertically overlap the upper surface 143BU of the landing portion 143B. In some example embodiments, an uppermost surface 145T of the second metal pattern 145 may be at the same vertical level or may be at substantially the same vertical level as the upper surface 143BU of the landing portion 143B, etc. For example, the uppermost surface 145T may be within +/−10% of the vertical level of the upper surface 143BU, etc.

In some example embodiments, the thickness of the second metal pattern 145 may be less than a first length, which is a length in the vertical direction (e.g., Z direction) between the upper surface 143AU of the extension portion 143A and an uppermost surface of the saddle fin portion of each of the plurality of active areas A1. In some other example embodiments, a thickness of the second metal pattern 145 may substantially be equal to (e.g., within +/−10%) or greater than the first length.

In some example embodiments, each of the first metal pattern 143 and the second metal pattern 145 may independently include a metal material, a conductive metal nitride, or any combination thereofs. In some example embodiments, each of the first metal pattern 143 and the second metal pattern 145 may independently include copper (Cu), tungsten (W), cobalt (Co), ruthenium (Ru), manganese (Mn), titanium (Ti), tantalum (Ta), aluminum (Al), molybdenum (Mo), lanthanum (La), lanthanum (LaO), titanium nitride (TiN), tantalum nitride (TaN), tungsten nitride (WN), titanium nitride (TiN), tantalum nitride (TaN), titanium silicon nitride (TiSiN), tungsten silicon nitride (WSiN), or any combinations thereof.

In some example embodiments, a constituent material of the first metal pattern 143 may be different from that of the second metal pattern 145. In some example embodiments, the first metal pattern 143 may have a first resistance, and the second metal pattern 145 may have a second resistance that is lower than the first resistance, but is not limited thereto. For example, the second metal pattern 145 may include a material having a lower resistance than the first metal pattern 143. For example, the first metal pattern 143 may include at least one of titanium (Ti) and/or tungsten (W), etc., and the second metal pattern 145 may include molybdenum (Mo), etc., but the example embodiments are not limited thereto.

In some example embodiments, the first metal pattern 143 may include a metal-containing liner (not shown) and/or a conductive core (not shown), which are sequentially stacked on the gate dielectric film 141, but is not limited thereto. In this case, the metal-containing liner may have a shape corresponding to the bottom profile of the gate trench 140T and may be on the gate dielectric film 141. The conductive core may fill a portion of the gate trench 140T on the metal-containing liner. A bottom surface of the conductive core may have a concave-convex shape corresponding to the bottom profile of the gate trench 140T, and an upper surface of the conductive core may extend relatively planarly, but the example embodiments are not limited thereto. In some example embodiments, the metal-containing liner may include Ti, Ta, W, TiN, TaN, WN, WCN, TiSiN, TaSiN, WSiN, or any combinations thereof, and/or the conductive core may include Mo, Cu, W, Co, Ru, Mn, Ti, Ta, Al, or any combinations thereof, and/or an alloy thereof, without being limited thereto.

According to some example embodiments, the line pattern 147 may be on the extension portion 143A of the first metal pattern 143. According to some example embodiments, the line pattern 147 may be spaced apart from the first metal pattern 143 with the second metal pattern 145 therebetween, or in other words, the second metal pattern 145 may be between the pattern 147 and the first metal pattern 143, but is not limited thereto, and for example, the line pattern 147 may include a greater or lesser number of metal patterns. According to some example embodiments, the first metal pattern 143 and/or the second metal pattern 145 may surround a bottom surface of the line pattern 147 and/or a sidewall 147S of the line pattern 147 inside the gate trench 140T, etc.

According to some example embodiments, the line pattern 147 may vertically overlap the extension portion 143A. The bottom surface of the line pattern 147 may be spaced apart from the upper surface 143AU of the extension portion 143A with the second metal pattern 145 therebetween. According to some example embodiments, the line pattern 147 may be apart from the landing portion 143B of the first metal pattern 143 in the first lateral direction (e.g., X direction). The sidewall 147S of the line pattern 147 in the first lateral direction (e.g., X direction) may face the first sidewall 143BS of the landing portion 143B with the second metal pattern 145 therebetween.

In some example embodiments, the line pattern 147 may not contact the upper surface 143BU of the landing portion 143B, and/or the line pattern 147 may not vertically overlap the upper surface 143BU of the landing portion 143B. In some example embodiments, the line pattern 147 may not contact the uppermost surface 145T of the second metal pattern 145, and/or may not vertically overlap the uppermost surface 145T of the second metal pattern 145. In some example embodiments, an upper surface 147U of the line pattern 147 may be at (or may substantially be at) the same vertical level as the upper surface 143BU of the landing portion 143B, but is not limited thereto. For example, the upper surface 147U may be within +/−10% of the vertical level of the upper surface 143BU, etc.

In some example embodiments, the line pattern 147 may include polysilicon or doped polysilicon, but is not limited thereto. For example, the line pattern 147 may assist in the electrical connection of the cell transistor (e.g., cell transistor CTR in FIG. 2) on the first metal pattern 143 and/or the second metal pattern 145, etc.

According to some example embodiments, the insulating capping pattern 149 may be on the first metal pattern 143, the second metal pattern 145, and/or the line pattern 147, etc., and fill the remaining space of the gate trench 140T. In some example embodiments, a bottom surface of the insulating capping pattern 149 may be in contact with the upper surface 143BU of the landing portion 143B, the uppermost surface 145T of the second metal pattern 145, and/or the upper surface 147U of the line pattern 147, etc. A sidewall of the insulating capping pattern 149 in the first lateral direction (e.g., X direction) may be in contact with the gate dielectric film 141 and may face the peripheral circuit active area A2 with portions of the gate dielectric film 141 and/or the insulating interface structure 130 therebetween.

In some example embodiments, the insulating capping pattern 149 may include a silicon oxide film, a silicon nitride film, a silicon oxynitride film, or any combinations thereof, but is not limited thereto.

According to some example embodiments, the IC device 100 may include a plurality of conductive contacts 150, which are respectively connected to the plurality of gate structures 140 in the interface area IA. According to some example embodiments, the plurality of conductive contacts 150 may be respectively inside a plurality of contact holes 150H, which pass through the insulating capping pattern 149 in the vertical direction (e.g., Z direction) in the interface area IA. In some example embodiments, the plurality of conductive contacts 150 may be electrically connected to a word line driver circuit (not shown) of the peripheral circuit area PCA. The plurality of conductive contacts 150 may correspond to the plurality of word line contacts WLC described with reference to FIG. 2, but are not limited thereto.

In FIG. 2, only a first side of the sides of the cell array area MCA in the first lateral direction (e.g., X direction) is illustrated in a view from above. In FIG. 2, some of the plurality of word line contacts WLC are illustrated as being connected to a first group of word lines WL, from among the plurality of word lines WL, and the remaining word lines WL (e.g., a second group of word lines WL) are illustrated as being not connected to the word line contact WLC. However, the second group of word lines WL may be connected to the remaining ones of the word line contacts WLC on a second side (not shown) of the cell array area MCA, which is opposite to the first side.

Referring back to FIGS. 3 and 4, the plurality of conductive contacts 150 may pass through the insulating capping pattern 149 and may contact the landing portion 143B of the first metal pattern 143. Each of the plurality of conductive contacts 150 may have a bottom surface contacting the upper surface 143BU of the landing portion 143B and may have a sidewall surrounded by the insulating capping pattern 149, etc. In some example embodiments, each of the plurality of conductive contacts 150 may be spaced apart from the second metal pattern 145 and/or may be spaced apart from the line pattern 147.

Although the bottom surface of each of the plurality of conductive contacts 150 are illustrated as being at the first vertical level LV1 in FIGS. 3 and 4, the example embodiments of the inventive concepts are not limited thereto. For example, a portion of the plurality of conductive contacts 150 may extend into the landing portion 143B, etc. In this case, the bottom surface of each of the plurality of conductive contacts 150 may be at a lower vertical level than the first vertical level LV1, but is not limited thereto.

In some example embodiments, each of the plurality of conductive contacts 150 may include a conductive barrier (not shown) covering an inner wall and/or a bottom surface of the contact hole 150H and/or a conductive plug (not shown) filling the contact hole 150H on the conductive barrier, but are not limited thereto. The conductive barrier may include Ti, Ta, W, TiN, TaN, WN, WCN, TiSiN, TaSiN, WSiN, or any combinations thereof, and/or the conductive plug may include Mo, Cu, W, Co, Ru, Mn, Ti, Ta, Al, any combinations thereof, and/or an alloy thereof, without being limited thereto.

In the IC device 100 according to one or more example embodiments, each of the plurality of gate structures 140 may include a plurality of metal patterns, e.g., the first metal pattern 143 and the second metal pattern 145, etc., and each of the plurality of conductive contacts 150 may be in contact with the first metal pattern 143 and may be apart from the second metal pattern 145, but are not limited thereto. Because the first metal pattern 143 and the second metal pattern 145 have different resistances, when the first metal pastern 143 and the second metal pattern 145 are exposed together to an electrolytic cleaning solution through the contact hole 150H, there may be a problem of corrosion of a component having a lower resistance from among the first metal pattern 143 and the second metal pattern 145, etc. In one or more example embodiments, the first metal pattern 143 may be exposed through the contact hole 150H, while the second metal pattern 145 may not be exposed by the contact hole 150H. Thus, the first metal pattern 143 or the second metal pattern 145 may be reduced and/or prevented from being damaged due to galvanic corrosion, etc. According to some example embodiments, the landing portion 143B of the first metal pattern 143 may have a greater length than the extension portion 143A thereof in the vertical direction (e.g., Z direction), and the second metal pattern 145 and the line pattern 147 may face a sidewall 143BS of the landing portion 143B, but is not limited thereto. Accordingly, each of the plurality of conductive contacts 150 may be relatively easily brought into contact with the landing portion 143B and may be reliably separated from the second metal pattern 145 and the line pattern 147, and thus, the structural and electrical reliability of the IC device 100 may be improved and/or made more reliable.

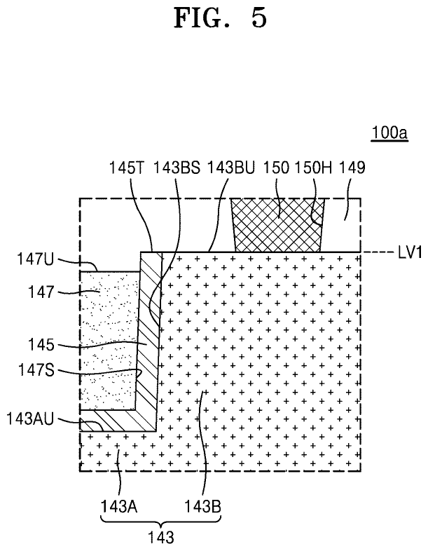

FIG. 5 is a cross-sectional view of an IC device 100a according to some example embodiments, which illustrates an example of the region “EX2” of FIG. 3. In FIG. 5, the same reference numerals are used to denote the same elements as in FIGS. 1 to 4, and thus, repeated descriptions thereof are omitted.

Referring to FIG. 5, in the IC device 100a, an upper surface 147U of a line pattern 147 may be at a vertical level lower than a first vertical level LV1, but is not limited thereto. For example, the upper surface 147U of the line pattern 147 may be at a lower vertical level than an upper surface 143BU of a landing portion 143B of a first metal pattern 143. For example, the upper surface 147U of the line pattern 147 may be at a vertical level lower than an uppermost surface 145T of a second metal pattern 145.

In some example embodiments, an upper portion of the second metal pattern 145, which covers the sidewall 143BS of the landing portion 143B, may be at a higher vertical level than the upper surface 147U of the line pattern 147, but is not limited thereto. For example, a sidewall of the upper portion may be in contact with the insulating capping pattern 149. For example, the sidewall 143BS of the landing portion 143B may face the insulating capping pattern 149 with the upper portion therebetween.

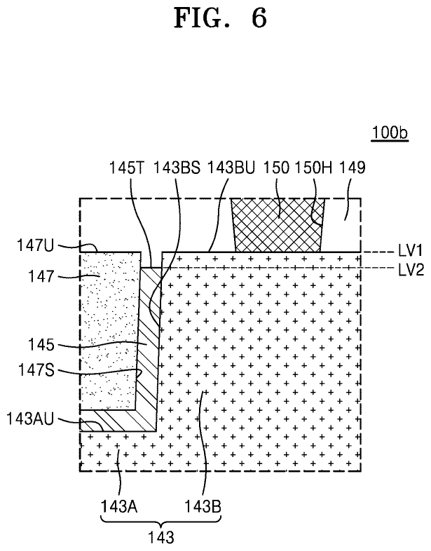

FIG. 6 is a cross-sectional view of an IC device 100b according to some example embodiments, which illustrates an example of the region “EX2” of FIG. 3. In FIG. 6, the same reference numerals are used to denote the same elements as in FIGS. 1 to 4, and thus, repeated descriptions thereof are omitted.

Referring to FIG. 6, in the IC device 100b, an uppermost surface 145T of a second metal pattern 145 may be at a second vertical level LV2 that is lower than the first vertical level LV1, but is not limited thereto. For example, the uppermost surface 145T of the second metal pattern 145 may be at a lower vertical level than an upper surface 143BU of a landing portion 143B. For example, the uppermost surface 145T of the second metal pattern 145 may be at a lower vertical level than an upper surface 147U of a line pattern 147.

In some example embodiments, an upper portion of a sidewall 143BS of the landing portion 143B may not be covered by the second metal pattern 145 and may be in contact with an insulating capping pattern 149. In some example embodiments, the upper portion of the sidewall 143BS may face a sidewall 147S of the line pattern 147 with the insulating capping pattern 149 therebetween. For example, the insulating capping pattern 149 may be in contact with the uppermost surface 145T of the second metal pattern 145 through a space between an upper portion of the sidewall 147S of the line pattern 147 and the upper portion of the sidewall 143BS of the landing portion 143B.

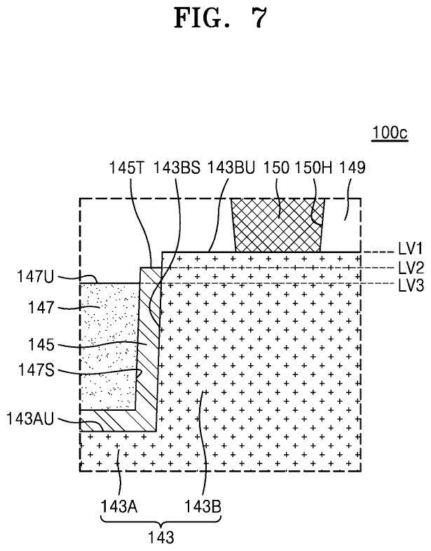

FIG. 7 is a cross-sectional view of an IC device 100c according to some example embodiments, which illustrates an example of the region “EX2” of FIG. 3. In FIG. 7, the same reference numerals are used to denote the same elements as in FIGS. 1 to 4, and thus, repeated descriptions thereof are omitted.

Referring to FIG. 7, in the IC device 100c, an uppermost surface 145T of the second metal pattern 145 may be at a second vertical level LV2 that is lower than a first vertical level LV1, and an upper surface 147U of the line pattern 147 may be at a third vertical level LV3 that is lower than the second vertical level LV2, but the example embodiments are not limited thereto. For example, an upper surface 143BU of a landing portion 143B, the uppermost surface 145T of the second metal pattern 145, and the upper surface 147U of the line pattern 147 may form a stepped structure of which a vertical level becomes lower toward the cell array area MCA, but are not limited thereto.

In some example embodiments, an upper portion of the sidewall 143BS of the landing portion 143B may not be covered by the second metal pattern 145 and may be in contact with an insulating capping pattern 149. In some example embodiments, an upper portion of the second metal pattern 145 may not be covered by the line pattern 147, and a sidewall of the upper portion may be in contact with the insulating capping pattern 149. In some example embodiments, the sidewall 143BS of the landing portion 143B may include a portion contacting the insulating capping pattern 149, a portion facing the insulating capping pattern 149 with the second metal pattern 145 therebetween, and a portion facing the line pattern 147 with the second metal pattern 145 therebetween.

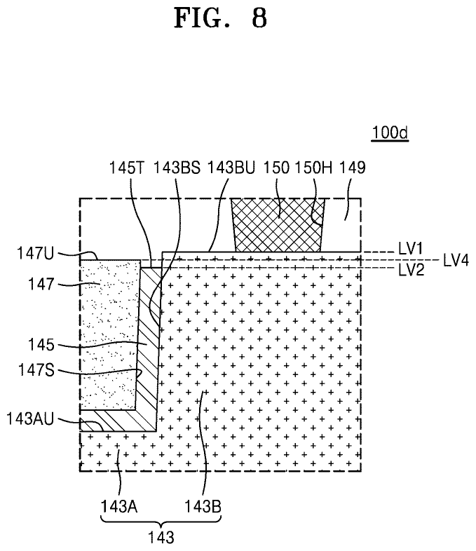

FIG. 8 is a cross-sectional view of an IC device 100d according to some example embodiments, which illustrates an example of the region “EX2” of FIG. 3. In FIG. 8, the same reference numerals are used to denote the same elements as in FIGS. 1 to 4, and thus, repeated descriptions thereof are omitted.

Referring to FIG. 8, in the IC device 100d, an uppermost surface 145T of a second metal pattern 145 may be at a second vertical level LV2 that is lower than the first vertical level LV1, and an upper surface 147U of a line pattern 147 may be at a fourth vertical level LV4 between the first vertical level LV1 and the second vertical level LV2, but the example embodiments are not limited thereto. For example, the upper surface 147U of the line pattern 147 may be at a lower vertical level than an upper surface 143BU of a landing portion 143B, and may be at a higher vertical level than the uppermost surface 145T of the second metal pattern 145.

In some example embodiments, an upper portion of a sidewall 143BS of the landing portion 143B may not be covered by the second metal pattern 145 and may be in contact with an insulating capping pattern 149. In some example embodiments, the upper portion of the sidewall 143BS may include a portion facing a sidewall 147S of the line pattern 147 with the insulating capping pattern 149 therebetween, but is not limited thereto. For example, the insulating capping pattern 149 may be in contact with the uppermost surface 145T of the second metal pattern 145 through a space between an upper portion of the sidewall 147S of the line pattern 147 and the upper portion of the sidewall 143BS of the landing portion 143B, etc.

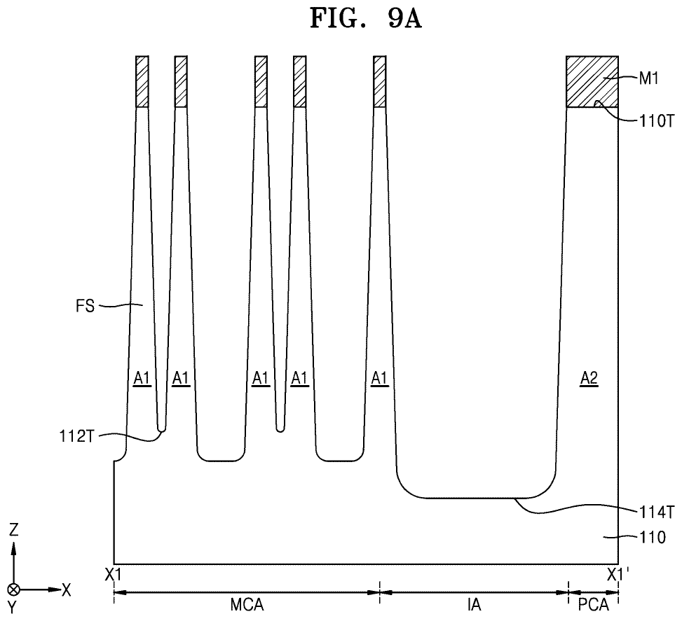

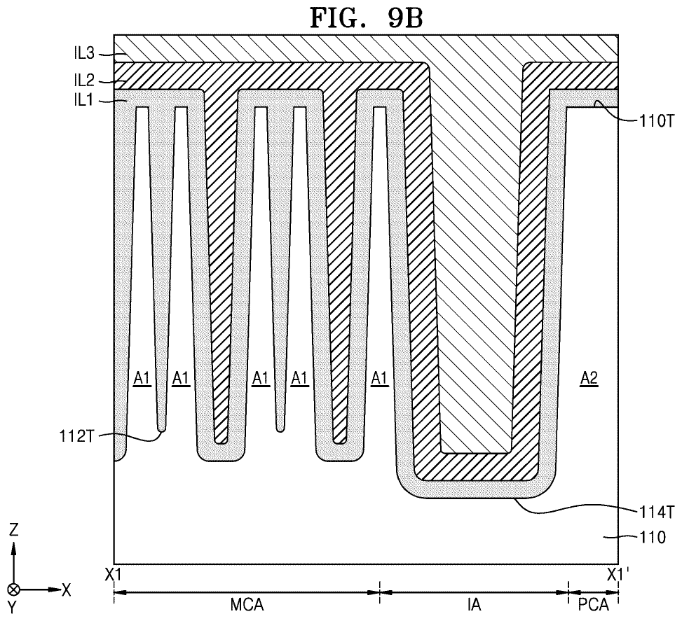

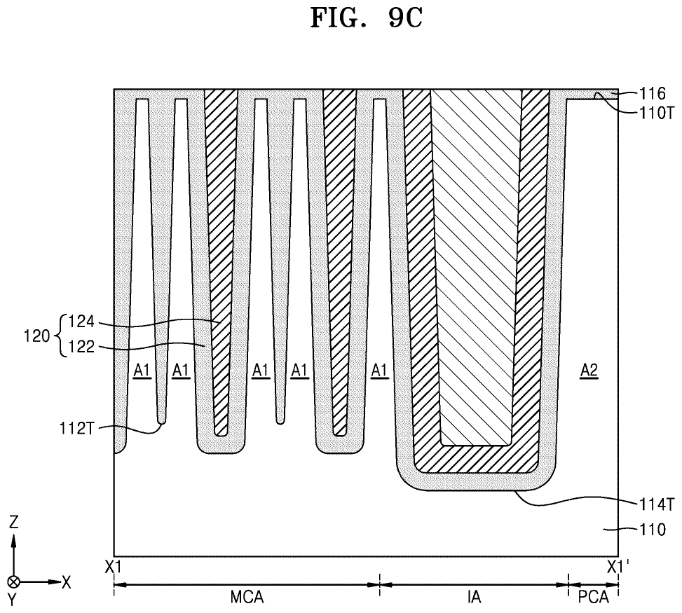

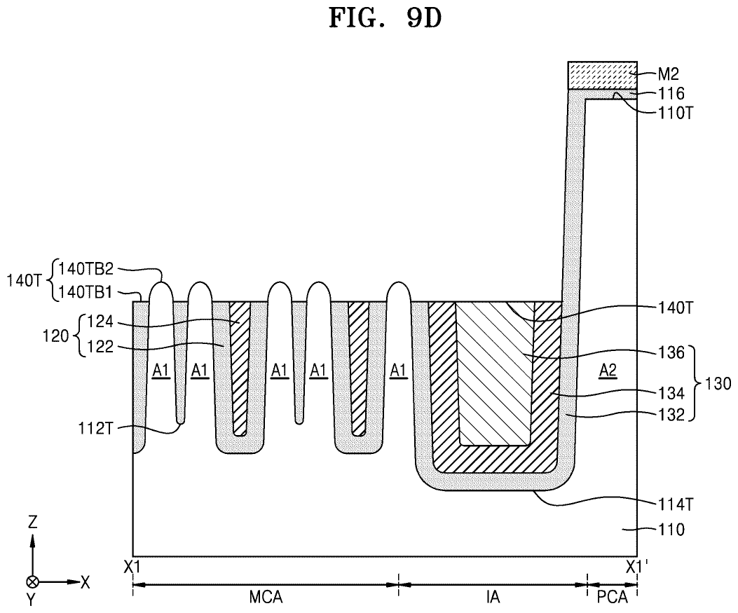

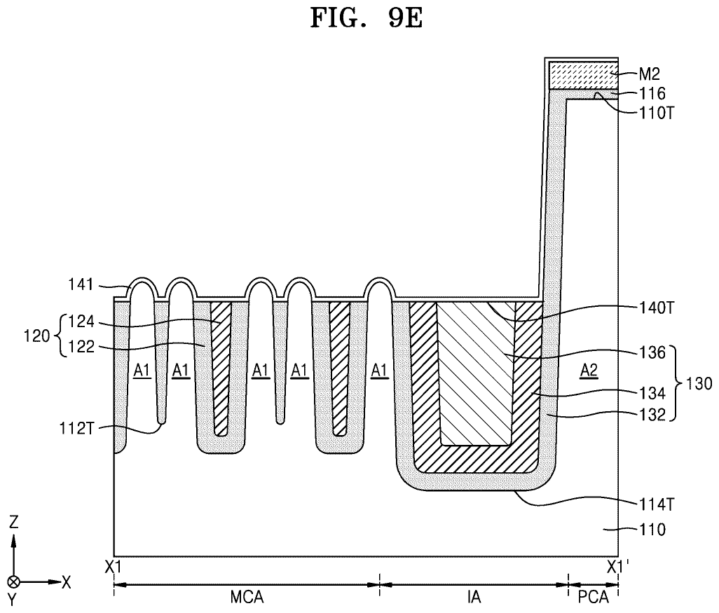

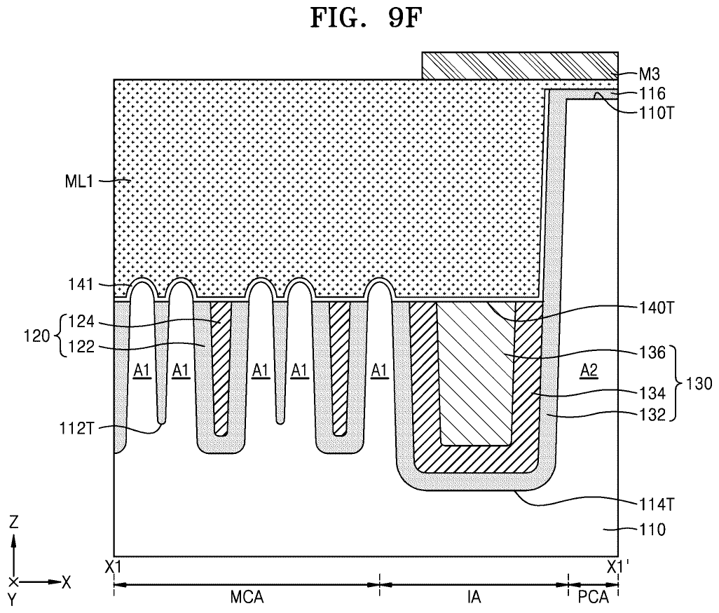

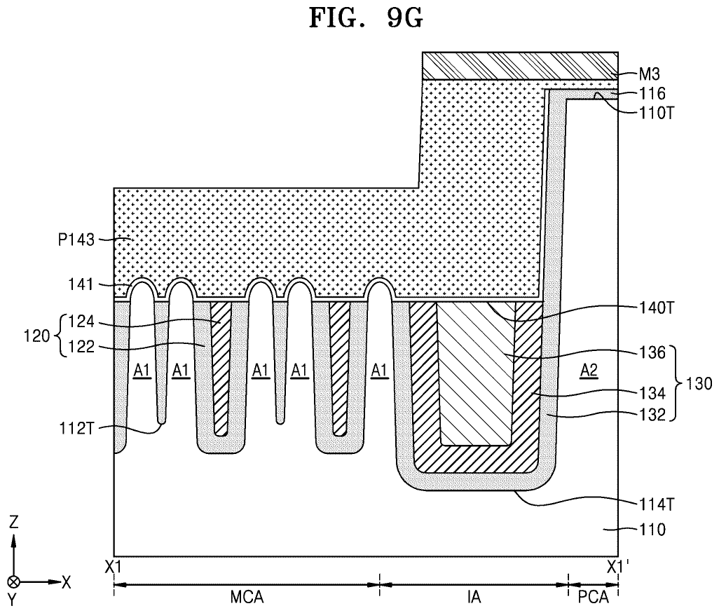

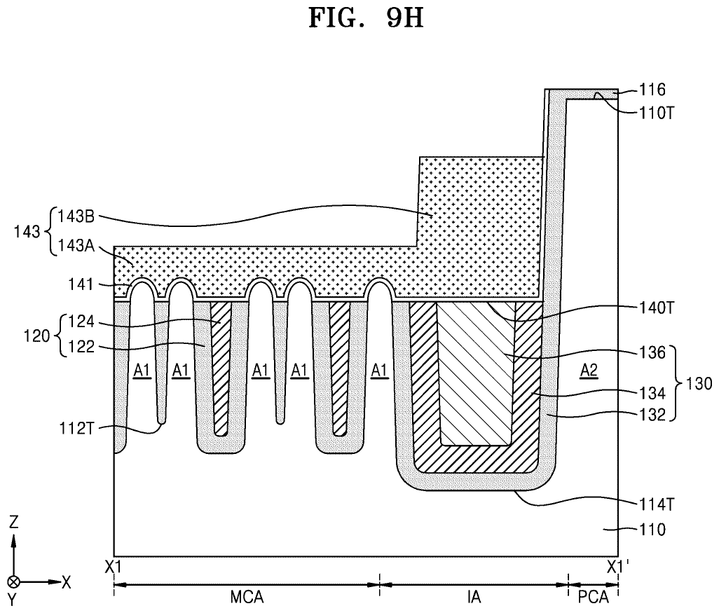

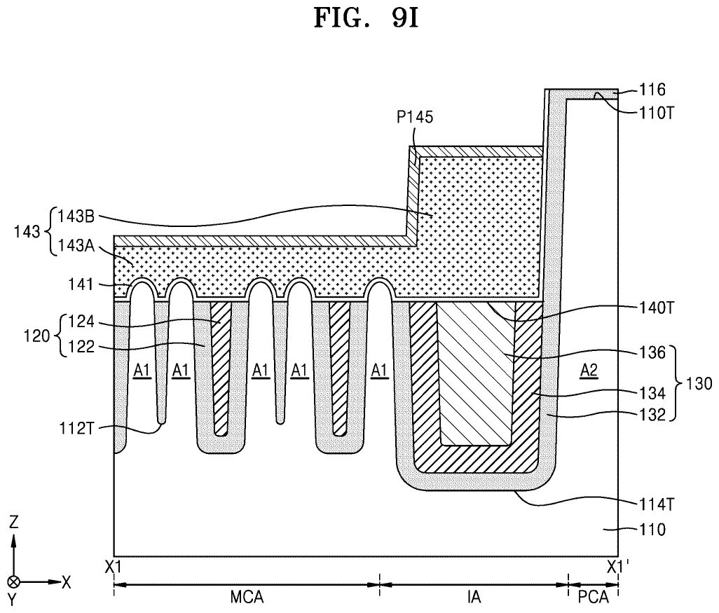

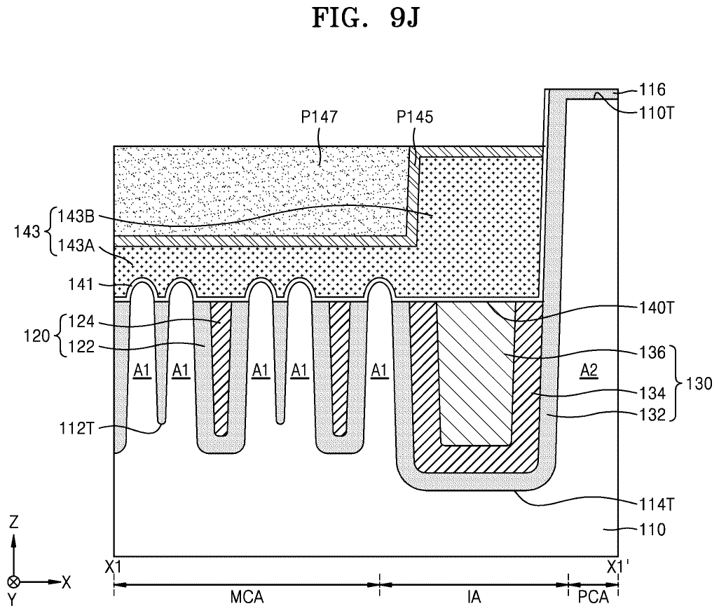

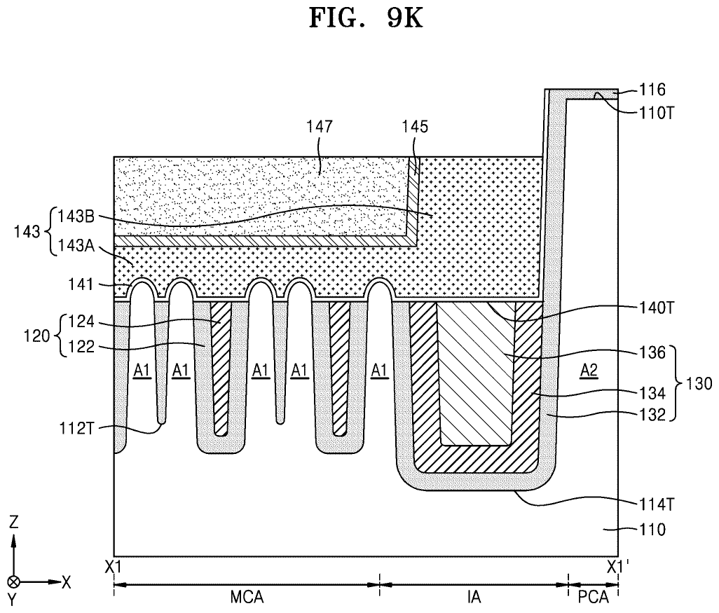

FIGS. 9A to 9K are cross-sectional views of some components in a portion corresponding to a cross-section taken along line X1-X1′ of FIG. 2. FIGS. 9A to 9K illustrate a process sequence of an example method of manufacturing an IC device 100 according to some example embodiments. Hereinafter, an example of a method of manufacturing the IC device 100 shown in FIGS. 1 to 4 is described with reference to FIGS. 9A to 9K. In FIGS. 9A to 9K, the same reference numerals are used to denote the same elements as in FIGS. 1 to 4, and thus, repeated descriptions thereof are omitted.

Referring to FIG. 9A, a substrate 110 having a cell array area MCA, a peripheral circuit area PCA, and/or an interface area IA between the cell array area MCA and the peripheral circuit area PCA may be prepared. According to some example embodiments, a first mask pattern M1 may be formed on an upper surface 110T of the substrate 110 to cover a portion of the cell array area MCA and/or a portion of the peripheral circuit area PCA, etc. Thereafter, the substrate 110 may be etched by using the first mask pattern M1 as an etch mask, and thus, a device isolation trench 112T may be formed in the cell array area MCA, and an interface trench 114T may be formed in the interface area IA. For example, by the device isolation trench 112T and the interface trench 114T, a plurality of active areas A1 of the substrate 110 may be defined in the cell array area MCA, and a peripheral circuit active area A2 of the substrate 110 may be defined in the peripheral circuit area PCA. Each of the plurality of active areas A1 may have a fin structure FS, but are not limited thereto. According to some example embodiments, the first mask pattern M1 may include an oxide film, polysilicon, or any combinations thereof, without being limited thereto.

Referring to FIG. 9A and the resultant structure of FIG. 9B, the first mask pattern M1 may be removed, and a first insulating film IL1, a second insulating film IL2, and/or a third insulating film IL3, etc., may be then sequentially formed on the substrate 110. Depending on a lateral width, a partial region of the device isolation trench 112T may be filled by only the first insulating film IL1, and another partial region thereof may be filled by the first insulating film IL1 and the second insulating film IL2, but the example embodiments are not limited thereto. Inside the interface trench 114T, the first insulating film IL1 may be formed to cover a bottom surface and an inner wall of the interface trench 114T, the second insulating film IL2 may be formed to fill a portion of the interface trench 114T on the first insulating film IL1, and the third insulating film IL3 may fill a space defined by the second insulating film IL2. In some example embodiments, each of the first insulating film IL1, the second insulating film IL2, and/or the third insulating film IL3 may be formed by using a chemical vapor deposition (CVD) process and/or an ALD process, etc., but are not limited thereto.

Referring to FIG. 9B and the resultant structure of FIG. 9C, each of the first insulating film IL1, the second insulating film IL2, and/or the third insulating film IL3, etc., on the upper surface 110T of the substrate 110 may be partially removed by using an etching process, and thus, a device isolation structure 120 and an insulating interface structure 130 may be formed. According to some example embodiments, the insulating thin film 116, which is part of insulating films formed to cover the upper surface 110T of the substrate 110 to form the device isolation structure 120 and the insulating interface structure 130, may remain covering the upper surface 110T of the substrate 110. For example, the insulating thin film 116 may protect a surface of the substrate 110 during a subsequent ion implantation process of implanting impurity ions into the substrate 110 and/or a subsequent etching process, but is not limited thereto.

Referring to FIG. 9C and the resultant structure of 9D, a second mask pattern M2 exposing a partial region of the cell array area MCA and/or a partial region of the interface area IA may be formed on the substrate 110, the device isolation structure 120, and/or the insulating interface structure 130, but is not limited thereto. In some example embodiments, portions of the plurality of active areas A1, a portion of the device isolation structure 120, and/or a portion of the insulating interface structure 130 may be etched by using the second mask pattern M2 as an etch mask, and thus, a plurality of gate trenches 140T may be formed, but the example embodiments are not limited thereto. According to some example embodiments, the second mask pattern M2 may include an oxide film, an amorphous carbon layer (ACL), a silicon oxynitride (SiON) film, or any combinations thereof, without being limited thereto. The gate trench 140T may include a first bottom surface 140TB1 exposing the device isolation structure 120 and/or a second bottom surface 140TB2 exposing saddle fin portions of the plurality of active areas A1, etc. Due to a difference in etch rate between the substrate 110 and the device isolation structure 120, the second bottom surface 140TB2 may be at a higher vertical level than the first bottom surface 140TB1, and a bottom surface of the gate trench 140T may have a concave-convex shape, but the example embodiments are not limited thereto.

Referring to FIG. 9D and the resultant structure of FIG. 9E, a gate dielectric film 141 may be formed to cover the inner wall and/or the bottom surface of the gate trench 140T, but the example embodiments are not limited thereto. In some example embodiments, the gate dielectric film 141 may be formed by using an ALD process, etc.

Referring to FIG. 9F, after the second mask pattern M2 is removed from the precursor structure of FIG. 9E, a first metal film ML1 may be formed to fill the gate trench 140T. In some example embodiments, the first metal film ML1 may be formed to cover an upper surface of the insulating thin film 116, etc. Thereafter, a third mask pattern M3 may be formed to cover the first metal film ML1 in the interface area IA and may expose the cell array area MCA. A constituent material of the third mask pattern M3 may be the same as that of the second mask pattern M2, which has been described above, but the example embodiments are not limited thereto.

Referring to FIG. 9F and the resultant structure of FIG. 9G, a portion of the first metal film ML1 may be removed by using the third mask pattern M3 as an etch mask to form a first preliminary mask pattern P143. During the removal process (e.g., etching process, etc.), although not shown, portions of the gate dielectric film 141, which cover two opposite inner walls of the gate trench 140T in a second lateral direction (e.g., Y direction), may be partially exposed, etc. In some example embodiments, an upper surface of the first preliminary mask pattern P143 may be at a vertical level in the cell array area MCA than in the interface area IA, and each of the end portions of the first preliminary mask pattern P143 in a first lateral direction (e.g., X direction) may have a stepped structure, but the example embodiments are not limited thereto.

Referring to FIG. 9G and the resultant structure of FIG. 9H, the third mask pattern M3 may be removed, and a portion of the first preliminary mask pattern P143 may be removed by using an etchback process to form a first metal pattern 143, but the example embodiments are not limited thereto. For example, inside the gate trench 140T, an upper surface of the first metal pattern 143 may have a profile similar to that of the upper surface of the first preliminary mask pattern P143, but is not limited thereto. The insulating thin film 116 may be exposed, and/or the gate dielectric film 141 may be exposed through an upper space of a landing portion 143B, etc.

Referring to FIG. 9H and the resultant structure of FIG. 9I, a second preliminary mask pattern P145 may be formed on a surface of the first metal pattern 143 (see FIG. 9H). In some example embodiments, the second preliminary mask pattern P145 may be formed to have a shape corresponding to a profile of a surface of the first metal pattern 143 exposed through the gate trench 140T, but is not limited thereto. For example, the second preliminary mask pattern P145 may be conformally formed on an upper surface (e.g., upper surface 143AU in FIG. 4, etc.) of an extension portion 143A, a first sidewall (e.g., first sidewall 143BS in FIG. 4, etc.) of the landing portion 143B, and/or an upper surface (e.g., upper surface 143BU in FIG. 4, etc.) of the landing portion 143B, but the example embodiments are not limited thereto.

In some example embodiments, the second preliminary mask pattern P145 may be formed by growing and/or depositing a metal material from and/or through the exposed surface of the first metal pattern 143, etc. For example, a metal material may be grown by using the first metal pattern 143 as a seed layer in a gas atmosphere containing a metal precursor, and thus, the second preliminary mask pattern P145 may be formed, but the example embodiments are not limited thereto.

In some example embodiments, although not shown, the first metal pattern 143 may have a structure in which a metal-containing liner (not shown) and a conductive core (not shown) are sequentially stacked, but the example embodiments are not limited thereto. The metal-containing liner may contact the gate dielectric film 141. The conductive core may be spaced apart from the gate dielectric film 141 and may be surrounded by the metal-containing liner. In this case, the second preliminary mask pattern P145 may be formed by growing and/or depositing a conductive material from a surface of the conductive core, etc. In some example embodiments, the metal-containing liner may include TiN, the conductive core may include W, and/or the second preliminary mask pattern P145 may include Mo, without being limited thereto.

Referring now to FIG. 9I and the resultant structure of FIG. 9J, a conductive film may be formed to fill the gate trench 140T, and a portion of the conductive film may be then removed by using an etchback process to form a preliminary line pattern P147 (see FIG. 9J). In some example embodiments, the preliminary line pattern P147 may include polysilicon or doped polysilicon, but is not limited thereto.

Referring now to FIG. 9J and the resultant structure of FIG. 9K, respective portions of the preliminary line pattern P147 and the second preliminary mask pattern P145 may be removed to form a line pattern 147 and a second metal pattern 145 (see FIG. 9K). During the removal process, a portion of the second preliminary mask pattern P145, which covers the upper surface 143BU of the landing portion 143B, may be removed.

Referring to FIG. 9K together with FIGS. 3 and 4, in the resultant structure of FIG. 9K, an insulating capping pattern 149 may be formed to fill the remaining portion of the gate trench 140T, a contact hole 150H passing through the insulating capping pattern 149 in a vertical direction (e.g., Z direction) may be formed in the interface area IA, and a cleaning process may be performed on the semiconductor structure. In some example embodiments, a solution used in the cleaning process may include an electrolytic solution containing at least one selected from ammonia, ammonium fluoride, sulfuric acid, hydrofluoric acid, and/or hydrogen chloride, etc.

In some example embodiments, the upper surface 143BU of the landing portion 143B may be exposed through the contact hole 150H. In this case, because the second metal pattern 145 is spaced apart from the contact hole 150H with the insulating capping pattern 149 therebetween, the second metal pattern 145 may not be exposed through the contact hole 150H. Accordingly, the first metal pattern 143 and the second metal pattern 145 may not be exposed together to the electrolytic solution for the cleaning process and the first metal pattern 143 and/or the second metal pattern 145 may be reduced and/or prevented from being damaged due to galvanic corrosion.

Afterwards, a conductive contact 150 may be formed to fill the contact hole 150H, and thus, the resultant structure shown in FIGS. 3 and 4 may be obtained.

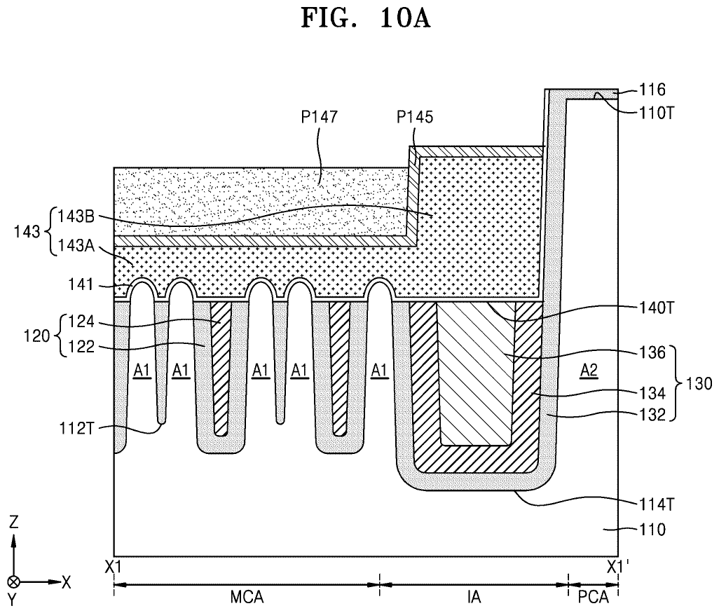

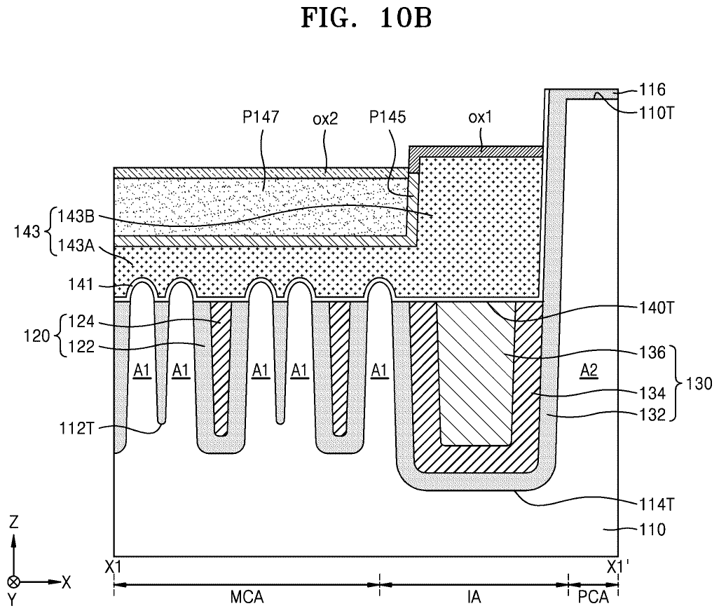

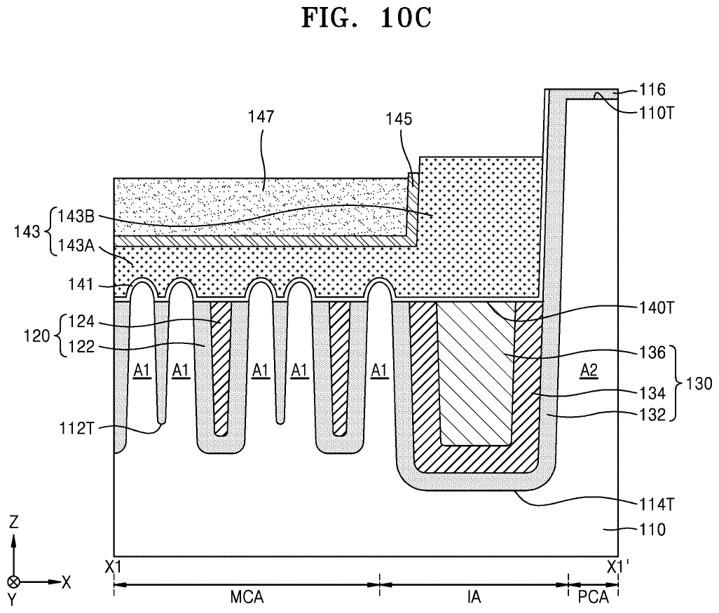

FIGS. 10A to 10C are cross-sectional views of some components in a portion corresponding to a cross-section taken along line X1-X1′ of FIG. 2, which illustrate a process sequence of a method of manufacturing an IC device 100c according to some example embodiments. Hereinafter, an example of a method of manufacturing the IC device 100c shown in FIGS. 1 to 4 and 7 is described with reference to FIGS. 10A to 10C, but the example embodiments are not limited thereto. In FIGS. 10A to 10C, the same reference numerals are used to denote the same elements as in FIGS. 1 to 4, 7, and 9A to 9K, and thus, repeated descriptions thereof are omitted.

By using the same method as that described with reference to FIGS. 9A to 9I, a plurality of gate trenches 140T may be formed in a semiconductor substrate 110, and a gate dielectric film 141, a first metal pattern 143, and/or a second metal pattern 145, etc., may be formed inside each of the plurality of gate trenches 140T, but the example embodiments are not limited thereto.

Referring to FIG. 10A, in the resultant structure of FIG. 9I, a conductive film may be formed to fill the gate trench 140T, and at least a portion of the conductive film may be then removed by using an etchback process to form at least one preliminary line pattern P147, etc. In this case, an upper surface of the preliminary line pattern P147 may be formed at a lower vertical level than an uppermost surface of the second preliminary mask pattern P145, but is not limited thereto. For example, the upper surface of the preliminary line pattern P147 may be formed at a lower vertical level than an upper surface 143BU of the landing portion 143B, but is not limited thereto.

Referring to FIG. 10B, in the resultant structure of FIG. 10A, an upper portion of the second preliminary mask pattern P145 and an upper portion of the preliminary line pattern P147 may each be oxidized using an oxidation process to form a plurality of oxide films, e.g., first oxide film ox1 and a second oxide film ox2, etc., but the example embodiments are not limited thereto. In some example embodiments, the first oxide film ox1 formed from the second preliminary mask pattern P145 may be in contact with an upper surface of the landing portion 143B and/or an upper portion of a sidewall of the landing portion 143B, but is not limited thereto. In some example embodiments, the second oxide film ox2 formed from the preliminary line pattern P147 may have an end portion in a first lateral direction (e.g., X direction), which may contact an unoxidized portion of the first oxide film ox1 and/or the second preliminary mask pattern P145, etc.

Referring to FIG. 10C, in the resultant structure of FIG. 10B, the first oxide film ox1 and the second oxide film ox2, etc., may be removed by using a stripping process (e.g., etching process, etc.) to form a second metal pattern 145 and/or a line pattern 147, etc. Accordingly, the upper surface (e.g., the upper surface 143BU in FIG. 7, etc.) of the landing portion 143B and an upper portion of a sidewall (e.g., upper portion of sidewall 143BS in FIG. 7, etc.) of the landing portion 143B may be exposed. In some example embodiments, an uppermost surface (e.g., uppermost surface 145T in FIG. 7, etc.) of the second metal pattern 145 may be exposed at a lower vertical level than the upper surface 143BU of the landing portion 143B, and an upper portion of a sidewall of the second metal pattern 145, which faces the line pattern 147, may be exposed. In some example embodiments, an upper surface (e.g., upper surface 147U in FIG. 7, etc.) of the line pattern 147 may be exposed at a lower vertical level than the uppermost surface 145T of the second metal pattern 145, but the example embodiments are not limited thereto.

Referring to FIG. 7 together with FIG. 10C, in the resultant structure of FIG. 10C, an insulating capping pattern 149 may be formed to fill the gate trench 140T, and a contact hole 150H may be then formed to expose the upper surface 143BU of the landing portion 143B in an interface area IA. Afterwards, a conductive contact 150 may be formed to fill the contact hole 150H, and thus, the resultant structure shown in FIG. 7 may be obtained.

While various example embodiments of the inventive concepts have been particularly shown and described, it will be understood that various changes in form and details may be made therein without departing from the spirit and scope of the following claims.

What is claimed is:

1. An integrated circuit device comprising:
a substrate comprising a cell array area and at least one interface area, the cell array area including a plurality of active areas, the at least one interface area including an insulating interface structure;
a gate structure extending across the plurality of active areas in a first lateral direction, the gate structure partially extending into the insulating interface structure of the interface area,
the gate structure including a first metal pattern, a line pattern, and a second metal pattern,
the first metal pattern including an extension portion and a landing portion, the extension portion vertically overlapping the plurality of active areas, and the landing portion vertically overlapping the insulating interface structure,
the line pattern on the extension portion of the first metal pattern, and
the second metal pattern between the first metal pattern and the line pattern; and
at least one conductive contact contacting the landing portion of the first metal pattern, the at least one conductive contact being spaced apart from the second metal pattern.

2. The integrated circuit device of claim 1, wherein the landing portion of the first metal pattern has a length in a vertical direction greater than a length of the extension portion of the first metal pattern in the vertical direction.

3. The integrated circuit device of claim 1, wherein a material included in the first metal pattern is different from a material included in the second metal pattern.

4. The integrated circuit device of claim 1, wherein
the landing portion of the first metal pattern includes a first sidewall facing the line pattern;
the first sidewall is spaced apart from the line pattern; and
the second metal pattern is between the first sidewall and the line pattern.

5. The integrated circuit device of claim 1, wherein
the first metal pattern has a stepped structure where the extension portion is connected to the landing portion; and
the second metal pattern has a shape corresponding to a surface profile of the first metal pattern.

6. The integrated circuit device of claim 1, wherein an upper surface of the landing portion of the first metal pattern is at a same vertical level as an uppermost surface of the second metal pattern.

7. The integrated circuit device of claim 1, wherein an upper surface of the line pattern is at a lower vertical level than an upper surface of the landing portion of the first metal pattern.

8. The integrated circuit device of claim 1, wherein the line pattern does not vertically overlap an upper surface of the landing portion of the first metal pattern.

9. The integrated circuit device of claim 1, wherein the line pattern is spaced apart from the at least one conductive contact.

10. The integrated circuit device of claim 1, wherein the second metal pattern does not contact an upper surface of the landing portion of the first metal pattern.

11. An integrated circuit device comprising:
a substrate including a cell array area, the cell array area including a plurality of active areas;
an insulating interface structure surrounding the cell array area, the insulating interface structure having a closed loop shape in a view from above;
a gate structure extending across the plurality of active areas in a first lateral direction, the gate structure partially extending into the insulating interface structure; and
at least one conductive contact contacting the gate structure on the insulating interface structure,
the gate structure including a first metal pattern, a second metal pattern, and a line pattern,
the first metal pattern including an extension portion and a landing portion, the first metal pattern having a stepped structure where the extension portion meets the landing portion,
the extension portion vertically overlapping the plurality of active areas and extending in the first lateral direction, and
the landing portion vertically overlapping the insulating interface structure and contacting the at least one conductive contact at a higher vertical level than an upper surface of the extension portion,
the second metal pattern covering the upper surface of the extension portion and a sidewall of the landing portion, the sidewall facing the cell array area,
the line pattern spaced apart from the first metal pattern, and
the second metal pattern between the line pattern and the first metal pattern.

12. The integrated circuit device of claim 11, wherein
the first metal pattern has a first resistance; and
the second metal pattern has a second resistance that is lower than the first resistance.

13. The integrated circuit device of claim 11, wherein an uppermost surface of the second metal pattern is at a lower vertical level than an upper surface of the landing portion.

14. The integrated circuit device of claim 11, wherein an upper surface of the line pattern is at a lower vertical level than the upper surface of the landing portion.

15. The integrated circuit device of claim 11, wherein the second metal pattern has a shape corresponding to a profile of the upper surface of the extension portion and a profile of the sidewall of the landing portion.

16. The integrated circuit device of claim 11, wherein
the at least one conductive contact is in contact with an upper surface of the landing portion; and
the at least one conductive contact is spaced apart from a second metal pattern.

17. The integrated circuit device of claim 11, wherein
the gate structure further includes an insulating capping pattern, the insulating capping pattern covering the first metal pattern, the second metal pattern, and the line pattern; and
the sidewall of the landing portion includes a portion contacting the insulating capping pattern.

18. An integrated circuit device comprising:
a substrate including a cell array area, a peripheral circuit area, and an interface area, the cell array area including a plurality of active areas, the peripheral circuit area including at least one peripheral circuit active area, and the interface area between the cell array area and the peripheral circuit area, the interface area including an insulating interface structure;
a gate structure extending across the plurality of active areas in a first lateral direction in the cell array area, the gate structure partially extending into the insulating interface structure of the interface area, the gate structure including a first metal pattern, a second metal pattern, and a line pattern,
the first metal pattern including an extension portion and a landing portion, the first metal pattern having a stepped structure where the extension portion meets the landing portion,
the extension portion vertically overlapping the plurality of active areas and extending in the first lateral direction, and
the landing portion vertically overlapping the insulating interface structure and having an upper surface at a higher vertical level than an upper surface of the extension portion,
the second metal pattern covering the upper surface of the extension portion and a sidewall of the landing portion,
the sidewall facing the cell array area,
the line pattern spaced apart from the first metal pattern, and
the second metal pattern between the line pattern and the first metal pattern; and
at least one conductive contact contacting the upper surface of the landing portion of the first metal pattern, the at least one conductive contact being spaced apart from the second metal pattern.

19. The integrated circuit device of claim 18, wherein the second metal pattern has a shape corresponding to a profile of the upper surface of the extension portion and a profile of the sidewall of the landing portion.

20. The integrated circuit device of claim 18, wherein the upper surface of the line pattern is at a lower vertical level than the upper surface of the landing portion.
